(19) United States
(12) Patent Application Publication
(10) Pub. No.: US 2010/0244129 A1
(43) Pub. Date: Sep. 30, 2010

(54) Semiconductor device and method of manufacturing semiconductor device

(75) Inventor: Kousuke Yoshida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/659,450

(22) Filed: Mar. 9, 2010

(30) Foreign Application Priority Data
Mar. 26, 2009 (JP) 2009-076065

(51) Int. Cl. H01L 29/78; H01L 21/336

(52) U.S. Cl. 257/335; 438/299; 257/E21.417; 257/E29.256

(57) ABSTRACT

Second-conductivity-type high dose impurity layers are formed in a device forming region, and function as the source and drain; a second-conductivity-type low dose impurity layer is provided around each of the second-conductivity-type high dose impurity layers so as to expand each second-conductivity-type high dose impurity layer in the depth-wise direction and in the direction of channel length, at least a part of the second-conductivity-type low dose impurity layer is positioned below the gate electrode, and the gate insulting film; and the gate insulating film has, at a portion thereof positioned above the second-conductivity-type low dose impurity layer, a sloped portion which continuously increases in the thickness from the center towards a side face of the gate electrode, without causing an inflection point.

This application is based on Japanese patent application No. 2009-076065 the content of which is incorporated hereinto by reference.

### BACKGROUND

1. Technical Field

The present invention relates to a semiconductor device capable of suppressing leakage current ascribable to inter-band tunneling current, and a method of manufacturing such semiconductor device.

2. Related Art

One possible example of high voltage MOS transistor may be given as illustrated in a sectional view in FIG. 6A. The transistor is formed in a first-conductivity-type semiconductor layer 500, and has a gate insulating film 530, a gate electrode 540, a second-conductivity-type high dose impurity layer 570 which serves as a source or drain, and a second-conductivity-type low dose impurity layer 560. The gate insulating film 530 and the gate electrode 540 are positioned over a channel-forming region 502. The second-conductivity-type low dose impurity layer 560 is formed so as to expand the second-conductivity-type high dose impurity layer 570 in the depth-wise direction and in the direction of channel length. The second-conductivity-type high dose impurity layer 570 is formed by implanting an impurity ion in a self-aligned manner, using the gate electrode 540 and sidewall 550 as masks.

When the gate voltage is turned off in the transistor, the second-conductivity-type high dose impurity layer 570 may occasionally be applied with high voltage which reversely biases the drain junction. In this case, the surficial portion of the second-conductivity-type low dose impurity layer 560 is inverted by the electric field applied through the gate electrode 540, and concentration of a first-conductivity-type carrier 590 elevates. On the other hand, a depletion layer 565 is formed in the second-conductivity-type low dose impurity layer 560.

FIG. 6B is a graph illustrating a relation between drain voltage and drain current in the OFF state of the transistor. Due to approach of the surficial portion of the depletion layer 565 close to the second-conductivity-type high dose impurity layer 570, and due to high electric field applied at the end portion of the gate electrode 540, drain voltage elevated at a certain level may induce not only junction leakage 601, but also leakage current 600 ascribable to inter-band tunneling current (gate-induced drain leakage current: GIDL current). Further elevation of the drain voltage may induce general junction breakdown current 602.

One possible technique of suppressing the leakage current may be thickening of the end portions of the gate insulating film of the transistor, typically as described in Japanese Laid-Open Patent Publication No. 2008-166570. In this Publication, the end portions of the gate insulating film are thickened by selectively and thermally oxidizing a semiconductor layer using an oxidation-resistant insulating film (silicon nitride film, for example) as a mask. The Publication describes that the gate insulating film is thickened in the end portions thereof by equal to or more than 20% and equal to or less than 40% as compared with the center portion, and is thickened over a width of equal to or larger than 0.08 μm and equal to or smaller than 0.16 μm.

### SUMMARY

In the configuration described in Japanese Laid-Open Patent Publication No. 2008-166570, electric field intensity at the end portions of the gate electrode might be moderated, but the gate electrode causes a sharp geometrical change in the portion thereof which overlaps with the edge of the oxidation-resistant insulating film used for forming the gate insulating film. For this reason, the electric field intensity elevates at the portions where the lower surface of the gate electrode causes the sharply geometrical change. Accordingly, the above-described GIDL current has been anticipated.

In one embodiment, there is provided a semiconductor device which includes:

a device isolation film formed in a first-conductivity-type semiconductor layer;

a device forming region partitioned by the device isolation film;

a channel-forming region provided to the device forming region;

a gate insulating film positioned over the channel-forming region;

a gate electrode positioned over the gate insulating film;

at least two second-conductivity-type high dose impurity layers formed in the device forming region, and function as the source and drain of a transistor; and

a second-conductivity-type low dose impurity layer formed in the device forming region, provided respectively around each of the second-conductivity-type high dose impurity layers so as to expand the second-conductivity-type high dose impurity layers in the depth-wise direction and in the direction of channel length, and has an impurity concentration lower than that of the second-conductivity-type high dose impurity layer,

at least a part of the second-conductivity-type low dose impurity layer being positioned below the gate electrode, and

the gate insulating film having, at a portion thereof positioned above the second-conductivity-type low dose impurity layer, a sloped portion which continuously increases in the thickness from the center towards a side face of the gate electrode, without causing an inflection point.

In the embodiment, the sloped portion formed in the gate insulating film is continuously increased in the thickness from the center towards a side face of the gate electrode, without causing an inflection point. The gate electrode, therefore, no longer has the portion causing the sharp geometrical change in the lower surface thereof, and thereby no longer has a portion where the electric field intensity increases. Accordingly, the GIDL current may be suppressed from generating.

In another embodiment, there is also provided a method of manufacturing a semiconductor device, the method includes:

partitioning a device forming region by forming a device isolation film in a first-conductivity-type semiconductor layer;

forming a gate insulating film over the device forming region;

forming a gate electrode over the gate insulating film;

forming, in the gate insulating film by thermally oxidizing the gate electrode, a sloped portion which continuously increases in the thickness from the center towards a side face of the gate electrode, without causing an inflection point;

forming a second-conductivity-type low dose impurity layer in the device forming region; and

forming a second-conductivity-type high dose impurity layer, which functions as the source and drain of a transistor, in the second-conductivity-type low dose impurity layer.

According to the present invention, GIDL current may be suppressed from generating.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a sectional view illustrating a configuration of a semiconductor device according to a first embodiment, and FIG. 1B is an enlarged view illustrating an essential portion;

FIGS. 2A to 2C are sectional views for explaining a method of manufacturing the semiconductor device illustrated in FIGS. 1A and 1B;

FIG. 3 is a graph for explaining effects of the semiconductor device illustrated in FIGS. 1A and 1B1;

FIG. 4 is a graph for explaining effects of the semiconductor device illustrated in FIGS. 1A and 1B;

FIG. 5 is a sectional view illustrating a configuration of a semiconductor device according to a second embodiment; and

FIG. 6A is a sectional view illustrating an exemplary high voltage transistor, and FIG. 6B is a graph for explaining effects of the semiconductor device illustrated in FIG. 6A.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be explained below, referring to the attached drawings. Note that any similar constituents in all drawings will given similar reference numerals or symbols, and explanations therefor will not always be repeated.

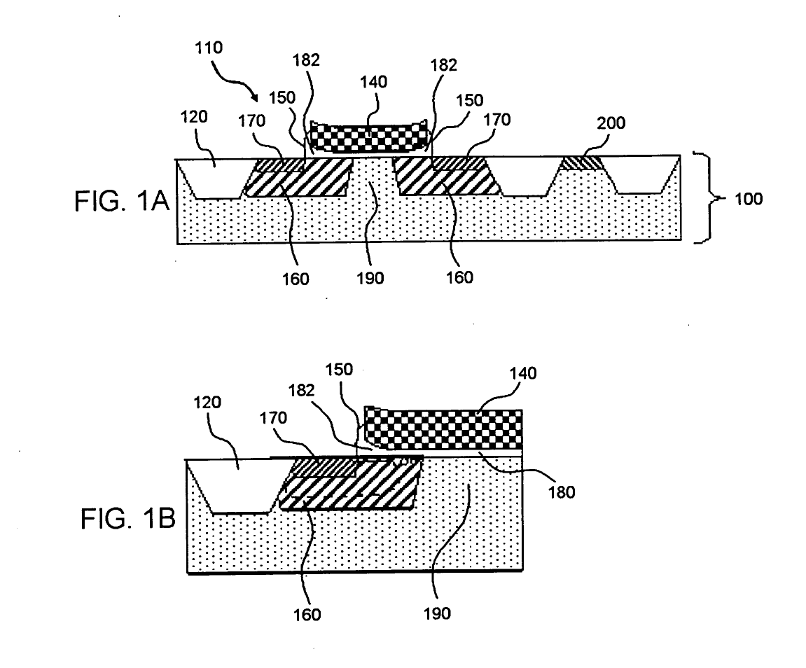

FIG. 1A is a sectional view illustrating a semiconductor device according to a first embodiment, and FIG. 1B is an enlarged view illustrating an essential portion of FIG. 1A. The semiconductor device has device isolation films 120 formed in a first-conductivity-type semiconductor layer 100, a device forming region 110, a channel-forming region 190, a gate insulating film 180, a gate electrode 140, at least two second-conductivity-type high dose impurity layers 170, and second-conductivity-type low dose impurity layers 160. The device forming region 110 is partitioned by the device isolation films 120. The channel-forming region 190 is provided to the device forming region 110. The gate insulating film 180 is positioned above the channel-forming region 190. The gate electrode 140 is positioned above the gate insulating film 180. The second-conductivity-type high dose impurity layers 170 are formed in the device forming region 110, and function as the source and drain of a transistor. The second-conductivity-type low dose impurity layers 160 are formed in the device forming region 110, and are respectively provided around the individual second-conductivity-type high dose impurity layers 170. The second-conductivity-type low dose impurity layers 160 are provided so as to expand the second-conductivity-type high dose impurity layers 170 in the depth-wise direction and in the direction of channel length, and has an impurity concentration lower than that of the second-conductivity-type high dose impurity layers 170. At least a part of the second-conductivity-type low dose impurity layer 160 is positioned below the gate electrode 140 and the gate insulating film 180. The gate insulating film 180 has, at a portion thereof positioned above each of the second-conductivity-type low dose impurity layers 160, a sloped portion 182 which continuously increases in the thickness from the center towards a side face of the gate electrode 140, without causing an inflection point.

The semiconductor layer 100 may typically be a semiconductor substrate such as a silicon substrate, or may be a semiconductor layer of an SOI (Silicon On Insulator) substrate. The gate insulating film 180 is typically a silicon oxide film. In this case, the thickness of the gate insulating film 180 is typically equal to or larger than 10 nm and equal to or smaller than 70 nm. Sidewalls 150 are formed on the side faces of the gate electrode 140.

In this embodiment, the gate electrode 140 has the length in the direction of channel length larger than the channel width, and is consequently positioned so as to overlap at the end portions thereof with the opposing second-conductivity-type low dose impurity layers 160. Since a part of the second-conductivity-type low dose impurity layers 160 may be positioned below the gate electrode 140, the transistor may be downsized. The width of the region where the gate electrode 140 and the second-conductivity-type low dose impurity layer 160 overlap with each other is equal to or larger than 0.2 μm and equal to or smaller than 1.2 μm. The distance between the second-conductivity-type high dose impurity layer 170 and the side face of the gate electrode 140 is equal to or larger than 0.2 μm and equal to or smaller than 3 μm.

The thickness of a portion of the gate insulating film 180 positioned below the center, as viewed in the direction of channel length, of the gate electrode 140 is equal to or larger than 10 nm and equal to or smaller than 70 nm. In the gate insulating film 180, a portion of the sloped portion 182 positioned below the side face of the gate electrode 140 has a thickness increased by equal to or more than 50% and equal to or less than 200%, relative to the thickness of a portion of the gate insulating film 180 positioned below the center, as viewed in the direction of channel length, of the gate electrode' 140.

The semiconductor layer 100 has a first-conductivity-type, impurity-diffused layer 200 formed therein, through which the reference voltage is applied to the semiconductor layer 100. The first-conductivity-type, impurity-diffused layer 200 is isolated by the device isolation film 120 from the device forming region 110.

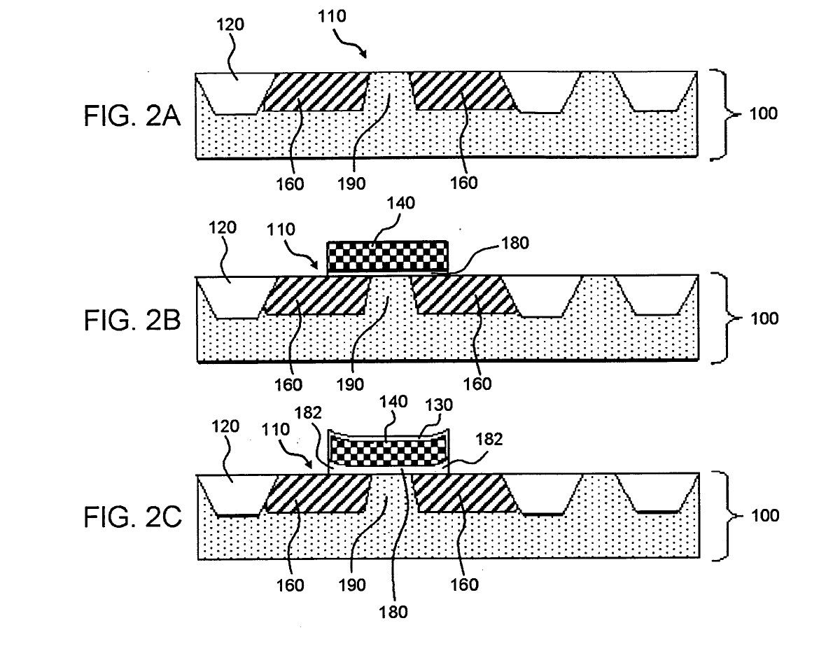

FIGS. 2A to 2C are sectional views illustrating a method of manufacturing the semiconductor device illustrated in FIGS. 1A and 1B. First, as illustrated in FIG. 2A, the device isolation films 120 are formed in the semiconductor layer 100. The semiconductor layer 100 is typically composed of a silicon layer. The device isolation films 120 may typically be formed by the STI (Shallow Trench Isolation) process, or may alternatively be formed by the LOCOS process. A mask pattern (not illustrated) is then formed, and a second-conductivity-type impurity ion is implanted into a part of the semiconductor layer 100. The mask pattern is then removed, and the semiconductor layer 100 is annealed. The second-conductivity-type low dose impurity layers 160 are thus formed.

Next, as illustrated in FIG. 2B, the gate insulating film 180 and the gate electrode 140 are formed. The gate insulating film 180 is typically composed of a silicon oxide film, and is typically formed by thermal oxidation. The gate electrode 140 is typically formed by a vapor deposition process (for'example, plasma-assisted CVD). The gate electrode 140 is typically composed of a silicon film, such as polysilicon film.

Next, as illustrated in FIG. 2C, the gate electrode 140 is thermally oxidized, typically by wet thermal oxidation. As a consequence, a gate electrode oxidized layer 130 is formed over the top surface and the side faces of the gate electrode 140, and at the same time, the sloped portions 182 are formed in the gate insulating film 180.

An insulating film, for forming later the sidewalls 150, is formed, and the insulating film is then anisotropically etched overall to form the sidewalls 150. In this process, a portion of the gate electrode oxidized layer 130 positioned on the top surface of the gate electrode 140 is etched off, and the other portions of the gate electrode oxidized layers 130 positioned on the side faces of the gate electrode 140 are integrated with the sidewalls 150.

Next, an second-conductivity-type impurity ion is implanted into a part of the semiconductor layer 100 in a self-aligned manner, to thereby form the second-conductivity-type high dose impurity layers 170 in the second-conductivity-type low dose impurity layers 160. One end portion of each second-conductivity-type high dose impurity layer 170 overlaps with each sidewall 150. In this way, the semiconductor device illustrated in FIG. 1A is formed.

Next, operations and effects of this embodiment will be explained. In this embodiment, the sloped portions 182 of the gate insulating film 180 are formed by thermally oxidizing the gate electrode 140. Accordingly, the gate insulating film 180 is continuously thickened in the sloped portions 182 without causing inflection point. The gate electrode 140 will, therefore, not have a sharp geometrical change formed therein. As a consequence, a region where electric field intensity becomes large will no longer be formed below the gate electrode 140, and thereby the GIDL current may be suppressed from generating.

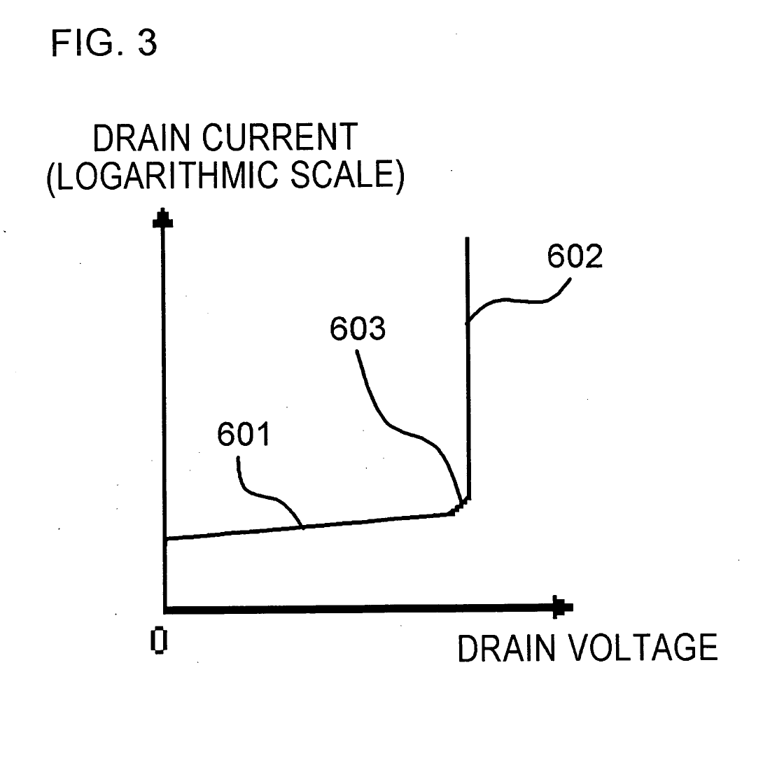

It is therefore understood, as illustrated in FIG. 3, that leakage current 603 ascribable to the GIDL current may be suppressed, even if the drain current elevates up to a certain level.

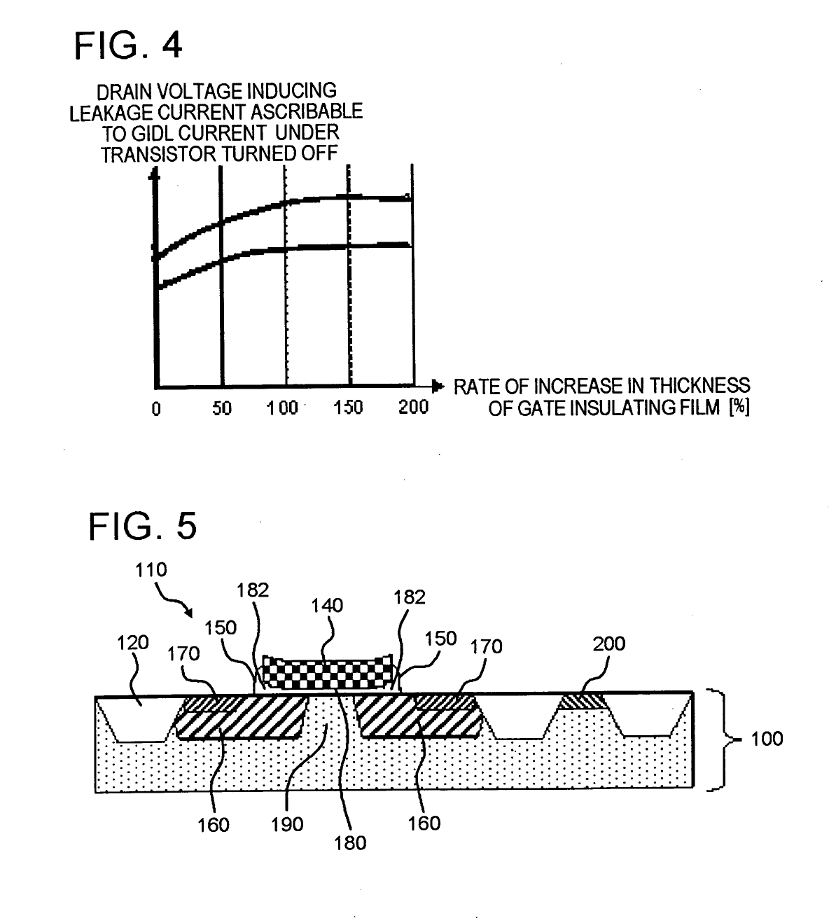

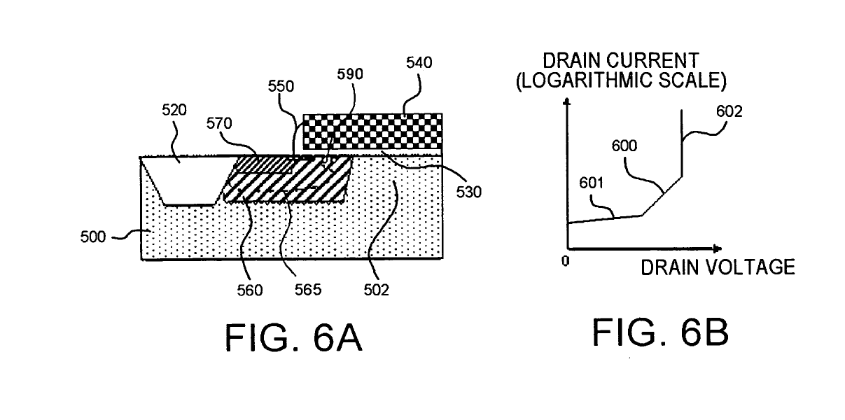

A portion of the sloped portion 182 positioned below the side face of the gate electrode 140 has a thickness increased by equal to or more than 50% and equal to or less than 200%, relative to the thickness of a portion of the gate insulating film 180 positioned below the center, as viewed in the direction of channel length, of the gate electrode 140. Effects derived from the configuration will be explained referring to FIG. 4.

FIG. 4 is a graph for illustrating relations between the rate of increase in the thickness of the gate insulating film 180 and drain voltage inducing leakage current ascribable to the GIDL current under the transistor turned off. The drain voltage inducing leakage current ascribable to GIDL current under the transistor turned off is found to increase when the rate of increase in the thickness is equal to or larger than 50%, as compared with the case where the rate of increase in the thickness is smaller than 50%. It is therefore understood that the drain voltage inducing leakage current ascribable to GIDL current under the transistor turned off may sufficiently be elevated, by adjusting the rate of increase in the thickness to equal to or larger than 50% and equal to or smaller than 200%, as described in this embodiment.

FIG. 5 is a sectional view illustrating a configuration of a semiconductor device according to a second embodiment. Procedures up to formation of the sidewalls 150 are same with those for manufacturing the semiconductor device described in the first embodiment, and will not repeatedly be explained here.

Upon completion of formation of the sidewalls 150, a mask pattern (not illustrated) is formed so as to cover the gate electrode 140 and the sidewalls 150. Next, a second-conductivity-type impurity ion is implanted, using the mask pattern and device isolation films 120 as a mask. By the process, the second-conductivity-type high dose impurity layers 170 are formed. Each of the second-conductivity-type high dose impurity layers 170 does not overlap with each sidewall 150. The distance between each second-conductivity-type high dose impurity layer 170 and the gate electrode 140 is typically equal to or larger than 0.2 μm and equal to or smaller than 3 μm.

Effects similar to those described the first embodiment may be obtained also by the semiconductor device manufactured by this embodiment. Since each second-conductivity-type high dose impurity layer 170 may appropriately be kept away from the sidewall 150 and the gate electrode 140, breakdown voltage in the OFF state of the transistor may be elevated. Since also the electric field in the transverse direction may be reduced, the GIDL current may be suppressed.

The embodiments of the present invention have been described in the above referring to the attached drawings, merely for the purpose of exemplification, while allowing adoption of any other various configurations other than those described in the above. For example, in the individual embodiments described in the above, the layouts of the second-conductivity-type high dose impurity layers 170 and the second-conductivity-type low dose impurity layers 160 are not limited to those illustrated in the drawings.

It is apparent that the present invention is not limited to the above embodiments, but may be modified and changed without departing from the scope and spirit of the invention.

What is claimed is:

1. A semiconductor device comprising:
a device isolation film formed in a first-conductivity-type semiconductor layer;
a device forming region partitioned by said device isolation film;
a channel-forming region provided to said device forming region;
a gate insulating film positioned over said channel-forming region;
a gate electrode positioned over said gate insulating film;
at least two second-conductivity-type high dose impurity layers formed in said device forming region, and function as the source and drain of a transistor; and
a second-conductivity-type low dose impurity layer formed in said device forming region, provided respectively around each of said second-conductivity-type high dose impurity layers so as to expand said second-conductivity-type high dose impurity layers in the depth-wise direction and in the direction of channel length, and has an impurity concentration lower than that of said second-conductivity-type high dose impurity layer,
at least a part of said second-conductivity-type low dose impurity layer being positioned below said gate electrode, and
said gate insulating film having, at a portion thereof positioned above said second-conductivity-type low dose impurity layer, a sloped portion which continuously increases in the thickness from the center towards a side face of said gate electrode, without causing an inflection point.

2. The semiconductor device as claimed in claim 1,
wherein in said gate insulating film, a portion of said sloped portion positioned below the side face of said gate electrode has a thickness increased by equal to or more than 50% and equal to or less than 200%, relative to the thickness of a portion of said gate insulating film positioned below the center, as viewed in the direction of channel length, of said gate electrode.

3. The semiconductor device as claimed in claim 1,
wherein the width of the region where said gate electrode and said second-conductivity-type low dose impurity layer overlap with each other is equal to or larger than 0.2 μm and equal to or smaller than 1.2 μm.

4. The semiconductor device as claimed in claim 1,
wherein said second-conductivity-type high dose impurity layer is equal to or more than 0.2 μm and equal to or less than 3 μm away from the edge of said gate electrode.

5. The semiconductor device as claimed in claim 1,
wherein the thickness of a portion of said gate insulating film positioned below the center, as viewed in the direction of channel length, of said gate electrode is equal to or larger than 10 nm and equal to or smaller than 70 nm.

6. A method of manufacturing a semiconductor device comprising:
partitioning a device forming region by forming a device isolation film in a first-conductivity-type semiconductor layer;
forming a gate insulating film over said device forming region;
forming a gate electrode over said gate insulating film;
forming, in said gate insulating film by thermally oxidizing said gate electrode, a sloped portion which continuously increases in the thickness from the center towards a side face of said gate electrode, without causing an inflection point;
forming a second-conductivity-type low dose impurity layer in said device forming region; and
forming a second-conductivity-type high dose impurity layer, which functions as the source and drain of a transistor, in said second-conductivity-type low dose impurity layer.

7. The method of manufacturing a semiconductor device as
claimed in claim 6, wherein said gate insulating film is a silicon oxide film, and
said gate electrode is a silicon film.
